(19) United States
(12) Patent Application Publication
(10) Pub. No.: US 2015/0123117 A1
(43) Pub. Date: May 7, 2015

(54) SEMICONDUCTOR DEVICE AND METHOD FOR MANUFACTURING SAME

(71) Applicant: Sharp Kabushiki Kaisha, Osaka-shi, Osaka (JP)

(72) Inventors: Kazuatsu Ito, Osaka-shi (JP); Tadayoshi Miyamoto, Osaka-shi (JP); Yasuyuki Ogawa, Osaka-shi (JP); Seiichi Uchida, Osaka-shi (JP)

(73) Assignee: Sharp Kabushshiki Kaisha, Osaka-shi, Osaka (JP)

(21) Appl. No.: 14/400,592

(22) PCT Filed: Apr. 26, 2013
(86) PCT No.: PCT/JP2013/062411

§ 371 Date: Nov. 12, 2014

(30) Foreign Application Priority Data
May 14, 2012 (JP) 2012-110655

(51) Int. Cl. H01L 29/786; H01L 21/441; H01L 29/66

(52) U.S. Cl. CPC H01L 29/7869; H01L 29/66969; H01L 21/441
USPC 257/43; 438/104

(57) ABSTRACT

A TFT substrate (100A) includes an oxide layer (15) which has a semiconductor region (5) and a conductor region (7) and in which the semiconductor region overlaps at least partially with a gate electrode (3a) with a first insulating layer (4) interposed between them, a protective layer (8) which covers the channel region of the semiconductor region, and a transparent electrode (9) which is arranged to overlap with at least a portion of the conductor region when viewed along a normal to the substrate (2). An end portion of the oxide layer is at least partially covered with the protective layer.

### TECHNICAL FIELD

The present invention relates to a semiconductor device which has been formed using an oxide semiconductor and a method for fabricating such a device, and more particularly relates to an active-matrix substrate for use in a liquid crystal display device or an organic EL display device and a method for fabricating such a substrate. In this description, the “semiconductor devices” include an active-matrix substrate and a display device which uses the active-matrix substrate.

### BACKGROUND ART

An active-matrix substrate for use in a liquid crystal display device and other devices includes switching elements such as thin-film transistors (which will be simply referred to herein as “TFTs”), each of which is provided for an associated one of pixels. An active-matrix substrate including This as switching elements is called a “TFT substrate”.

As for TFTs, a TFT which uses an amorphous silicon film as its active layer (and will be referred to herein as an “amorphous silicon TFT”) and a TFT which uses a polysilicon film as its active layer (and will be referred to herein as a “polysilicon TFT”) have been used extensively.

Recently, people have proposed that an oxide semiconductor be used as a material for the active layer of a TFT instead of amorphous silicon or polysilicon. Such a TFT will be referred to herein as an “oxide semiconductor TFT”. Since an oxide semiconductor has higher mobility than amorphous silicon, the oxide semiconductor TFT can operate at higher speeds than an amorphous silicon TFT. Also, such an oxide semiconductor film can be formed by a simpler process than a polysilicon film.

Patent Document No. 1 discloses a method for fabricating a TFT substrate including oxide semiconductor TFTs. According to the method disclosed in Patent Document No. 1, a TFT substrate can be fabricated in a reduced number of manufacturing process steps by forming a pixel electrode with the resistance of the oxide semiconductor film locally lowered.

### CITATION LIST

### Patent Literature

Patent Document No. 1: Japanese Laid-Open Patent Publication No. 2011-91279

### SUMMARY OF INVENTION

### Technical Problem

The present inventors discovered via experiments that if the TFT substrate as disclosed in Patent Document No. 1 should be fabricated with the number of manufacturing process steps and the manufacturing cost cut down, each wiring structure of the TFT substrate would be such a structure as to cause leakage current easily, thus possibly resulting in a decreased yield.

The present inventors perfected our invention in order to overcome such a problem by providing a semiconductor device which can be fabricated by a simple process with the decrease in yield checked and a method for fabricating such a semiconductor device.

### Solution to Problem

A semiconductor device according to an embodiment of the present invention includes: a substrate; a gate electrode formed on the substrate; a first insulating layer formed on the gate electrode; an oxide layer which is formed on the first insulating layer and which includes a semiconductor region and a conductor region, wherein the semiconductor region overlaps at least partially with the gate electrode with the first insulating layer interposed between them; a source electrode and a drain electrode which are electrically connected to the semiconductor region; a source line electrically connected to the source electrode; a protective layer which covers a channel region of the semiconductor region, does not cover at least a portion of the conductor region, and covers at least partially an end portion of the oxide layer; and a transparent electrode arranged so as to overlap at least partially with the conductor region when viewed along a normal to the substrate.

In one embodiment, the drain electrode contacts with a portion of the upper surface of the conductor region.

In one embodiment, the semiconductor device further includes an interlayer insulating layer formed on the protective layer, the transparent electrode is formed on the interlayer insulating layer, and the conductor region overlaps at least partially with the transparent electrode with the interlayer insulating layer interposed between them.

In one embodiment, the first insulating layer is formed on the transparent electrode, and the conductor region overlaps at least partially with the transparent electrode with the first insulating layer interposed between them.

In one embodiment, the semiconductor device further includes a second insulating layer. The second insulating layer is formed on the gate electrode, and the transparent electrode is formed on the second insulating layer.

In one embodiment, the semiconductor device further includes a second insulating layer. The second insulating layer is formed on the transparent electrode, and the gate electrode is formed on the second insulating layer.

A semiconductor device according to another embodiment of the present invention includes: a substrate; a gate electrode formed on the substrate; a gate insulating layer formed on the gate electrode; an oxide layer which is formed on the gate insulating layer and which includes a semiconductor region and a conductor region, wherein the semiconductor region overlaps at least partially with the gate electrode with the gate insulating layer interposed between them; a source electrode and a drain electrode which are electrically connected to the semiconductor region; a source line electrically connected to the source electrode; an interlayer insulating layer formed on a source line layer including the source and drain electrodes and the source line; and a transparent electrode arranged so as to overlap at least partially with the conductor region with the interlayer insulating layer interposed between them when viewed along a normal to the substrate. The transparent electrode has a hole which overlaps with the source line layer when viewed along a normal to the substrate.

In one embodiment, the semiconductor device further includes a protective layer which contacts with a channel region of the semiconductor region and which covers at least a portion of the source line layer. The hole overlaps with a portion of the source line layer which is not covered with the protective layer when viewed along a normal to the substrate.

In one embodiment, the semiconductor device further includes a reducing insulating layer which has the property of reducing an oxide semiconductor included in the semiconductor region. The reducing insulating layer contacts with the conductor region but does not contact with the semiconductor region, and covers the source line layer at least partially. And the hole overlaps with a portion of the source line layer which is not covered with the reducing insulating layer when viewed along a normal to the substrate.

In one embodiment, the oxide layer includes In, Ga and Zn.

A method for fabricating a semiconductor device according to an embodiment of the present invention includes the steps of: (a) providing a substrate; (b) forming a gate electrode on the substrate; (c) forming a first insulating layer on the gate electrode; (d) forming an oxide semiconductor film on the first insulating layer; (e) performing the step (e1) of forming a conductive film on the oxide semiconductor film and patterning the oxide semiconductor film and the conductive film using a single photomask, thereby forming an oxide semiconductor layer and a source line layer including a source electrode, a drain electrode and a source line, and the step (e2) of forming a protective layer which covers a channel region of the oxide semiconductor layer and at least a part of an end portion of the oxide semiconductor layer and performing a resistance lowering process to lower the resistance of a portion of the oxide semiconductor layer, thereby forming a conductor region and leaving another portion of the oxide semiconductor layer that has not had its resistance lowered as a semiconductor region; and (f) forming a transparent electrode which overlaps at least partially with the conductor region when viewed along a normal to the substrate.

In one embodiment, the step (f) is performed after the step (e) has been performed.

In one embodiment, the step (f) is performed between the steps (a) and (b).

In one embodiment, the step (f) is performed between the steps (c) and (d).

A method for fabricating a semiconductor device according to another embodiment of the present invention includes the steps of: (a) providing a substrate; (b) forming a gate electrode on the substrate; (c) forming a gate insulating layer on the gate electrode; (d) forming an oxide semiconductor film on the gate insulating layer; (e) forming a conductive film on the oxide semiconductor film and patterning the oxide semiconductor film and the conductive film using a single photomask, thereby forming an oxide semiconductor layer and a source line layer including a source electrode, a drain electrode and a source line; (f) performing a resistance lowering process to lower the resistance of a portion of the oxide semiconductor layer, thereby forming a conductor region and leaving another portion of the oxide semiconductor layer that has not had its resistance lowered as a semiconductor region; (g) forming an interlayer insulating layer on the conductor region; and (h) forming a transparent electrode which overlaps at least partially with the conductor region with the interlayer insulating layer interposed between them when viewed along a normal to the substrate so that a hole which overlaps with the source line layer when viewed along a normal to the substrate is cut through the transparent electrode.

In one embodiment, the method further includes the step (i) of forming a protective layer which contacts with a channel region of the semiconductor region and which covers the source line layer at least partially between the steps (e) and (f), and the hole is cut so as to overlap with a portion of the source line layer which is not covered with the protective layer when viewed along a normal to the substrate.

In one embodiment, the step (f) includes the step (f1) of forming a reducing insulating layer which has the property of reducing an oxide semiconductor included in the semiconductor region. The reducing insulating layer is formed so as to cover the source line layer at least partially. The resistance lowering process is performed by the reducing insulating layer. And the hole is cut so as to overlap with a portion of the source line layer which is not covered with the reducing insulating layer when viewed along a normal to the substrate.

### Advantageous Effects of Invention

Embodiments of the present invention provide a semiconductor device which can be fabricated by a simple process with the decrease in yield checked and a method for fabricating such a semiconductor device.

### BRIEF DESCRIPTION OF DRAWINGS

FIG. 1 (a) is a schematic plan view of a TFT substrate 100A according to an embodiment of the present invention. (b) is a schematic cross-sectional view as viewed on the plane A-A′ shown in FIG. 1(a). And (c) is a schematic cross-sectional view as viewed on the plane B-B′ shown in FIG. 1(a).

FIG. 2 A schematic cross-sectional view illustrating a TFT substrate 900 as a comparative example.

FIG. 3 A schematic cross-sectional view of a liquid crystal display device 500 including the TFT substrate 100A.

FIGS. 4 (a) to (c) are schematic plan views illustrating an exemplary method for fabricating a TFT substrate 100A according to an embodiment of the present invention.

FIGS. 5 (a) to (d) are schematic cross-sectional views illustrating an exemplary series of manufacturing process steps to fabricate the TFT substrate 100A.

FIGS. 6 (a) and (b) are schematic cross-sectional views illustrating an exemplary series of manufacturing process steps to fabricate the TFT substrate 100A.

FIG. 7 A schematic cross-sectional view of a TFT substrate 100B(1) according to another embodiment of the present invention.

FIG. 8 (a) is a schematic cross-sectional view of a liquid crystal display device 600 including the TFT substrate 100B(1), and (b) is a schematic cross-sectional view of a liquid crystal display device 700 including the TFT substrate 100B(1).

FIG. 9 (a) to (e) are schematic cross-sectional views illustrating respective manufacturing process steps to fabricate the TFT substrate 100B(1) according to another embodiment of the present invention.

FIG. 10 A schematic cross-sectional view of a TFT substrate 100B(2) according to still another embodiment of the present invention.

FIG. 11 (a) to (c) are schematic cross-sectional views illustrating respective manufacturing process steps to fabricate the TFT substrate 100B(2) according to still another embodiment of the present invention.

FIG. 12 A schematic cross-sectional view of a TFT substrate 100C according to yet another embodiment of the present invention.

FIG. 13 (a) to (c) are schematic cross-sectional views illustrating respective manufacturing process steps to fabricate the TFT substrate 100C according to yet another embodiment of the present invention.

### DESCRIPTION OF EMBODIMENTS

Hereinafter, a semiconductor device as an embodiment of the present invention will be described with reference to the accompanying drawings. The semiconductor device of this embodiment includes a thin-film transistor with an active layer made of an oxide semiconductor (which will be referred to herein as an “oxide semiconductor TFT”). It should be noted that the semiconductor device of this embodiment just needs to include an oxide semiconductor TFT and is broadly applicable to an active-matrix substrate and various kinds of display devices and electronic devices.

In the following description, a semiconductor device as an embodiment of the present invention will be described as being applied to an oxide semiconductor TFT for use in a liquid crystal display device. It should be noted that the TFT substrate to be described below shares some common features with the TFT substrates that are disclosed in PCT International Applications Nos. PCT/JP2013/051422, PCT/JP2013/051415, and PCT/JP2013/051417, the entire disclosures of which are hereby incorporated by reference.

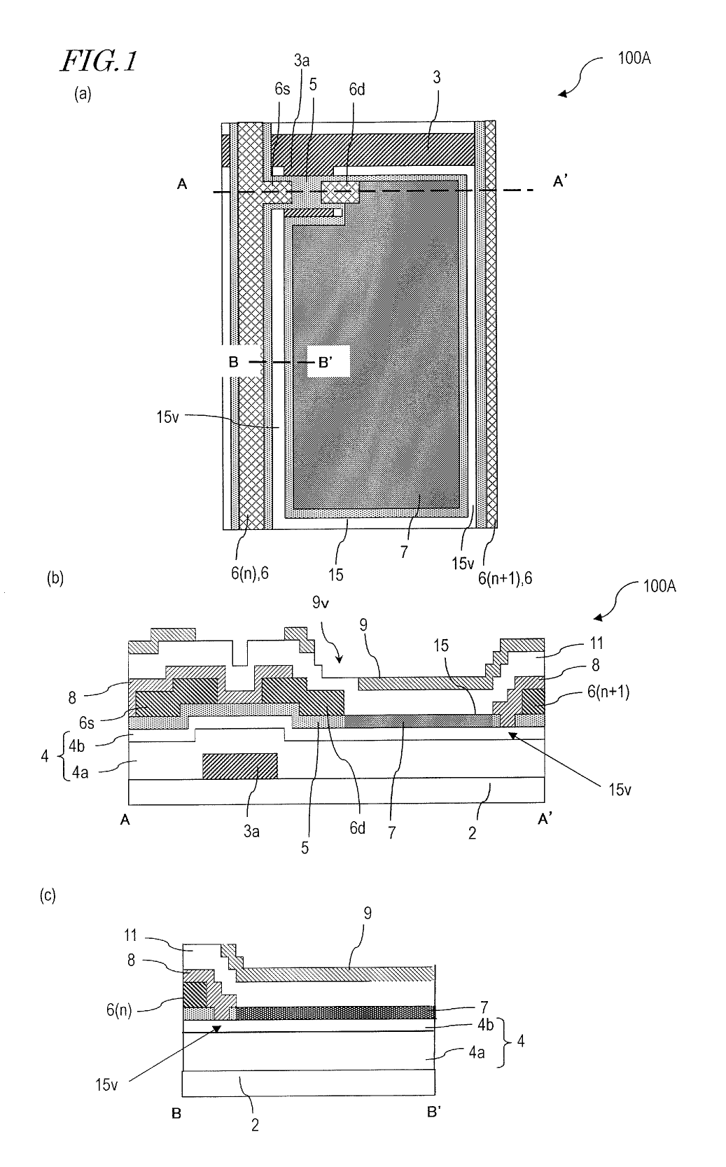

FIG. 1(a) is a schematic plan view of a TFT substrate 100A according to this embodiment. FIG. 1(b) is a schematic cross-sectional view of the TFT substrate 100A as viewed on the plane A-A′ shown in FIG. 1(a). And FIG. 1(c) is a schematic cross-sectional view of the TFT substrate 100A as viewed on the plane B-B′ shown in FIG. 1(a).

As shown in FIGS. 1(a) and 1(b), this TFT substrate 100A includes a substrate 2, a gate electrode 3a which is formed on the substrate 2, and an insulating layer (gate insulating layer) 4 which is formed on the gate electrode 3a. The TFT substrate 100A further includes an oxide layer 15 (which will be sometimes referred to herein as an “oxide semiconductor layer” and) which is formed on the insulating layer 4 and which includes a semiconductor region 5 and a conductor region 7. The semiconductor region 5 overlaps at least partially with the gate electrode 3a with the insulating layer 4 interposed between them. The TFT substrate 100A further includes a source electrode 6s and a drain electrode 6d which are electrically connected to the semiconductor region 5, a source line 6 which is electrically connected to the source electrode 6s, a protective layer 8 which covers a channel region of the semiconductor region 5 and does not cover at least a portion of the conductor region 7, and a transparent electrode 9 which is arranged so as to overlap at least partially with the conductor region 7 when viewed along a normal to the substrate 2. An end portion of the oxide layer 15 is at least partially covered with the protective layer 8. In this description, an electrode or line which is formed out of the same conductive film as the source electrode 6s will be sometimes referred to herein as a “source line layer”, which includes the source electrode 6s, the drain electrode 6d and the source line 6, for example. The protective layer 8 may also be arranged to cover the source line layer at least partially.

The oxide layer 15 includes a semiconductor region 5 and a conductor region 7. The conductor region 7 has a lower electrical resistance than the semiconductor region 5.

The electrical resistance of the conductor region 7 may be 100 kΩ/□ or less, for example, and is suitably 10 kΩ/□ or less. Although it depends on what processing method is taken to lower the resistance, the conductor region 7, for example, may be doped more heavily with a dopant (such as boron) than the semiconductor region 5 is. The semiconductor region 5 is arranged to overlap with the gate electrode 3a with the gate insulating layer 4 interposed between them, and functions as an active layer for a TFT. Meanwhile, the conductor region 7 is arranged in contact with the semiconductor region 5 and may function as a transparent electrode (such as a pixel electrode), for example.

In this embodiment, an interlayer insulating layer is formed on the protective layer 8, a transparent electrode 9 is formed on the interlayer insulating layer 11, and the conductor region 7 overlaps at least partially with the transparent electrode 9 with the interlayer insulating layer 11 interposed between them. Furthermore, the transparent electrode 9 has a hole 9v which overlaps with the source line layer (e.g., the drain electrode 6d) when viewed along a normal to the substrate 2. The hole 9v suitably overlaps with a portion of the source line layer (e.g., the drain electrode 6d) which is not covered with the protective layer 8 when viewed along a normal to the substrate 2. By cutting the hole 9v at such a position, leakage current will be hardly generated between the transparent electrode 9 and the source line layer (such as the drain electrode 6d). It should be noted that the hole 9v could overlap with the protective layer 8 due to misalignment or depending on the etching condition. Furthermore, a portion of the transparent electrode 9 may overlap with the source line layer (such as the drain electrode 6d) and the protective layer 8 when viewed along a normal to the substrate 2. Then, the storage capacitance can be increased.

In addition, according to this embodiment, a conductor region 7 to be a pixel electrode, for example, can be formed by locally lowering the resistance of the oxide layer 15, and the rest of the oxide layer 15 which is left as a semiconductor can turn into a semiconductor region 5 to be the active layer of the TFT. As a result, the manufacturing process can be simplified.

As shown in FIG. 1(a), a plurality of source lines 6 are arranged parallel to the column direction of the substrate 2. Inside each pixel, a hole 15v has been cut in the vicinity of the oxide layer 15. Portions of the hole 15v are located in the vicinity of a source line 6(n) and in the vicinity of the source line 6(n+1) of an adjacent pixel. It should be noted that the oxide layer 15 is arranged between the source lines 6(n) and 6(n+1). The direction in which an end portion of the oxide layer 15 runs on the source line 6(n) side is substantially parallel to the direction in which the source line 6(n) runs. The direction in which another end portion of the oxide layer 15 runs on the source line 6(n+1) side is substantially parallel to the direction in which the source line 6(n+1) runs.

As shown in FIGS. 1(b) and 1(c), by covering the end portion(s) of the oxide layer 15 on the source line 6(n) side and/or on the source line 6(n+1) side with an insulating layer (such as the protective layer 8), it is possible to prevent leakage current from flowing from those source line(s) 6(n) and/or 6(n+1) into the conductor region 7, for example. As shown in FIGS. 1(b) and 1(c), those end portions of the oxide layer 15 on the source line 6(n) side and on the source line 6(n+1) side are suitably entirely covered with an insulating layer. More suitably, the hole 15v is entirely filled with an insulating layer.

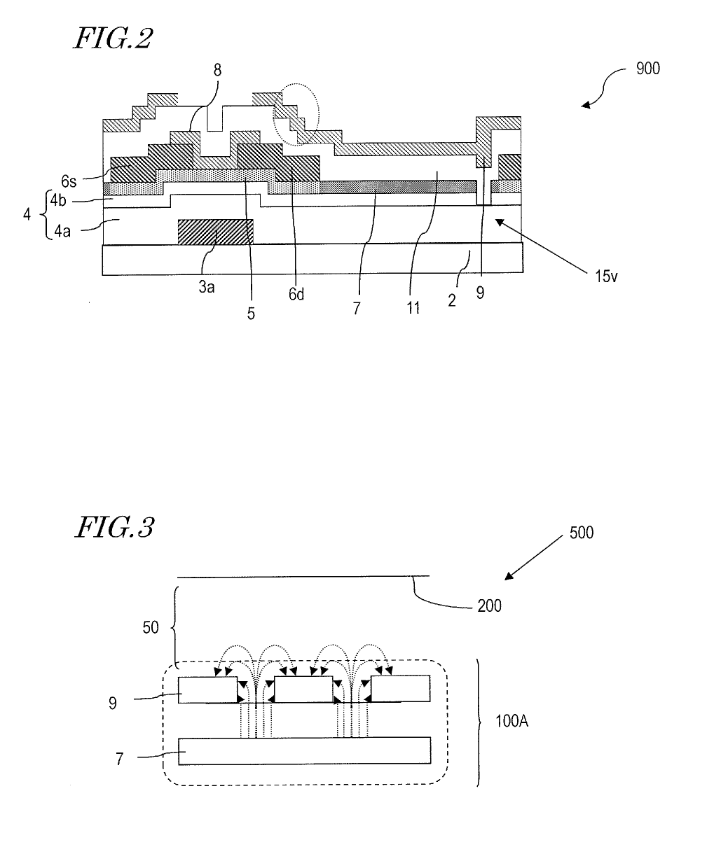

Furthermore, as shown in FIGS. 1(b) and 1(c), the insulating layer that fills the hole 15v is suitably the protective layer 8, for example. The reason will be described with reference to FIG. 2.

FIG. 2 is a schematic cross-sectional view illustrating a TFT substrate 900 as a comparative example. In the TFT substrate 900, any component also included in the TFT substrate 100A and having substantially the same function as its counterpart is identified by the same reference numeral as its counterpart's and description thereof will be omitted herein to avoid redundancies.

In this TFT substrate 900, the hole 15v is filled with the interlayer insulating layer 11, not with the protective layer 8, and the transparent electrode 9 does not have the hole 9v, which are differences from the TFT substrate 100A.

As shown in FIG. 2, if the hole 15v were filled with the interlayer insulating layer 11, the shape of the hole 15v would be transferred on the shape of the interlayer insulating layer 11, which would in turn be transferred on the shape of the transparent electrode 9 that is formed on the interlayer insulating layer 11. As a result, the distance between the transparent electrode 9 and the source line 6 becomes shorter, thus generating leakage current between them and causing a failure.

For that reason, the insulating layer to fill the hole 15v should be able to avoid shortening the distance between the transparent electrode 9 and the source line 6, and therefore, the hole 15v is suitably filled with the protective layer 8 that is not likely to shorten the distance between the transparent electrode 9 and the source line 6 as is done in this embodiment. Also, if the hole 15v is filled with the protective layer 8 and if the source line 6 is covered at least partially with the protective layer 8, the distance between the source line 6 and the transparent electrode 9 will increase too much to generate leakage current between them easily.

Furthermore, in the TFT substrate 900, its transparent electrode 9 does not have the hole 9v described above, and therefore, a portion of the transparent electrode 9 is located too close to the drain electrode 6s in some region (which is indicated by the dotted circle in FIG. 2), where leakage current will be generated easily.

On the other hand, in the TFT substrate 100A, a hole 9v has been cut through that portion of the transparent electrode 9 that would otherwise be located too close to the drain electrode 6d. Consequently, leakage current will not be generated easily between the transparent electrode 9 and the drain electrode 6d.

In this embodiment, the source and drain electrodes 6s and 6d are arranged to contact with the upper surface of the semiconductor region (active layer) 5. If the conductor region 7 is used as a pixel electrode, the drain electrode 6d is electrically connected to the conductor region 7. In that case, a portion of the drain electrode 6d suitably contacts with a portion of the upper surface of the conductor region 7. If such a structure is adopted, the conductor region 7 can be formed to substantially reach an end portion of the drain electrode 6d, and therefore, this TFT substrate 100A can have a higher aperture ratio than the TFT substrate disclosed in Patent Document No. 1.

Hereinafter, the respective components of this TFT substrate 100 will be described in detail one by one.

The substrate 2 is typically a transparent substrate and may be a glass substrate, for example, but may also be a plastic substrate. Examples of the plastic substrates include a substrate made of either a thermosetting resin or a thermoplastic resin and a composite substrate made of these resins and an inorganic fiber (such as glass fiber or a non-woven fabric of glass fiber). A resin material with thermal resistance may be polyethylene terephthalate (PET), polyethylene naphthalate (PEN), polyether sulfone (PES), an acrylic resin, or a polyimide resin, for example. Also, when used in a reflective liquid crystal display device, the substrate 2 may also be a silicon substrate.

The gate electrode 3a is electrically connected to a gate line 3. The gate electrode 3a and the gate line 3 may have a multilayer structure, of which the upper layer is a W (tungsten) layer and the lower layer is a TaN (tantalum nitride) layer, for example. Alternatively, the gate electrode 3a and the gate line 3 may also have a multilayer structure consisting of Mo (molybdenum), Al (aluminum) and Mo layers or may even have a single-layer structure, a double layer structure, or a multilayer structure consisting of four or more layers. Still alternatively, the gate electrode 3a may be made of an element selected from the group consisting of Cu (copper), Al, Cr (chromium), Ta (tantalum), Ti (titanium), Mo and W or an alloy or metal nitride which is comprised mostly of any of these elements. The thickness of the gate electrode 3a and gate line 3 may fall within the range of about 50 nm to about 600 nm, for example. In this embodiment, the gate electrode 3a and gate line 3 have a thickness of approximately 420 nm.

The gate insulating layer 4 may also be a single layer or a multilayer structure of SiO₂ (silicon dioxide), SiNₓ (silicon nitride), SiOₓN_{Y} (silicon oxynitride, where x>y), SiNₓO_{y} (silicon nitride oxide, where x>y), Al₂O₃ (aluminum oxide), or tantalum oxide (Ta₂O₅). The thickness of the gate insulating layer 4 suitably falls within the range of about 50 nm to about 600 nm. To prevent dopants from diffusing from the substrate 2, the insulating layer 4a is suitably made of SiNₓ or SiNₓO_{y} (silicon nitride oxide, where x>y). Moreover, to prevent the semiconductor properties of the semiconductor region 5 from deteriorating, the insulating layer 4b is suitably made of either SiO₂ or SiOₓN_{y} (silicon oxynitride, where x>y). Furthermore, to form a dense gate insulating layer 4 which causes little gate leakage current at low temperatures, the gate insulating layer 4 is suitably formed with a rare gas of Ar (argon), for example, used.

The oxide layer 15 may be formed out of an In—Ga—Zn—O based film including In (indium), Ga (gallium) and Zn (zinc) at a ratio of 1:1:1. The ratio of In, Ga and Zn may be selected appropriately.

The oxide layer 15 does not have to be formed out of an In—Ga—Zn—O based film, but may also be formed out of any other suitable oxide film such as a Zn—O based (ZnO) film, an In—Zn—O based (IZO™) film, a Zn—Ti—O based (ZTO) film, a Cd—Ge—O based film, a Cd—Pb—O based film, a CdO (cadmium oxide) film, or an Mg—Zn—O based film. Furthermore, the oxide layer 15 may also be made of ZnO in an amorphous state, a polycrystalline state, or a microcrystalline state (which is a mixture of amorphous and polycrystalline states) to which one or multiple dopant elements selected from the group consisting of Group I, Group XIII, Group XIV, Group XV and Group XVII elements have been added, or may even be ZnO to which no dopant elements have been added at all. An amorphous oxide film is suitably used as the oxide layer 15, because the semiconductor device can be fabricated at a low temperature and can achieve high mobility in that case. The thickness of the oxide layer 15 may fall within the range of about 30 nm to about 100 nm, for example (e.g., approximately 50 nm).

The oxide layer 15 of this embodiment includes a high-resistance portion which functions as a semiconductor and a low-resistance portion which has a lower electrical resistance than the high-resistance portion does. In the example illustrated in FIG. 1, the high-resistance portion includes the semiconductor region 5, while the low-resistance portion includes the conductor region 7. Such an oxide layer 15 may be formed by lowering the resistance of a portion of the oxide semiconductor film. Although it depends on what method is used to lower the resistance, the low-resistance portion may be doped more heavily with a p-type dopant (such as B (boron)) or an n-type dopant (such as P (phosphorus)) than the high-resistance portion is. The low-resistance portion may have an electrical resistance of 100 kΩ/sq or less, and suitably has an electrical resistance of 10 kΩ/sq or less.

The source line layer (including the source and drain electrodes 6s and 6d and the source line 6 in this case) may have a multilayer structure comprised of Ti, Al and Ti layers, for example. Alternatively, the source line layer may also have a multilayer structure comprised of Mo, Al and Mo layers or may even have a single-layer structure, a double layer structure or a multilayer structure consisting of four or more layers. Furthermore, the source line layer may also be made of an element selected from the group consisting of Al, Cr, Ta, Ti, No and W, or an alloy or metal nitride comprised mostly of any of these elements. The thickness of the source line layer may fall within the range of about 50 nm to about 600 nm (e.g., approximately 350 nm), for example.

This TFT substrate 100A may be used in a liquid crystal display device 500, for example.

FIG. 3 is a schematic cross-sectional view of a liquid crystal display device 500 including the TFT substrate 100A according to this embodiment of the present invention.

As shown in FIG. 3, the TFT substrate 100A may be used in a fringe field switching (FFS) mode liquid crystal display device 500, for example. In this case, the conductor region 55 that forms the lower layer is used as a pixel electrode (to which a display signal voltage is applied), and the transparent electrode 9 that forms the upper layer is used as a common electrode (to which either a common voltage or a counter voltage is applied). At least one slit is cut through the transparent electrode 9. An FFS mode liquid crystal display device 500 with such a configuration is disclosed in Japanese Laid-Open Patent Publication No. 2011-53443, for example, the entire disclosure of which is hereby incorporated by reference.

This liquid crystal display device 500 includes the TFT substrate 100A, a counter substrate 200, and a liquid crystal layer 50 interposed between the TFT substrate 100A and the counter substrate 200. In this liquid crystal display device 500, no counter electrode such as a transparent electrode of ITO, for example, is arranged on the surface of the counter substrate 200 to face the liquid crystal layer 50. Instead, a display operation is carried out by controlling the alignments of liquid crystal molecules in the liquid crystal layer 50 with a lateral electric field which is generated by the conductor region (pixel electrode) 7 and the transparent electrode (common electrode) 9 that are formed on the TFT substrate 100A.

Hereinafter, an exemplary method for fabricating the semiconductor device 100A according to an embodiment of the present invention will be described.

A method for fabricating a semiconductor device (TFT substrate) 100A according to an embodiment of the present invention includes the steps of: (a) providing a substrate 2; (b) forming a gate electrode 3a on the substrate 2; (c) forming an insulating layer (gate insulating layer) 4 on the gate electrode 3a; and (d) forming an oxide semiconductor film on the insulating layer 4. The method for fabricating the TFT substrate 100A further includes the step (e) of performing the step (e1) of forming a conductive film on the oxide semiconductor film and patterning the oxide semiconductor film and the conductive film using a single photomask, thereby forming an oxide semiconductor layer 15 and a source line layer including a source electrode 6s, a drain electrode 6d and a source line 6, and the step (e2) of forming a protective layer 8 which protects a channel region of the oxide semiconductor layer 15 and at least a part of an end portion of the oxide semiconductor layer 15 and performing a resistance lowering process to lower the resistance of a portion of the oxide semiconductor layer 15, thereby forming a conductor region 7 and leaving another portion of the oxide semiconductor layer 15 that has not had its resistance lowered as a semiconductor region 5. And the method for fabricating the TFT substrate 100A further includes the step (f) of forming a transparent electrode 9 which overlaps at least partially with the conductor region 7 when viewed along a normal to the substrate 2.

The step (f) may be performed after the step (e) has been performed.

Alternatively, the step (f) may also be performed between the steps (a) and (b).

Still alternatively, the step (f) may also be performed between the steps (c) and (d).

A method for fabricating a TFT substrate 100A according to another embodiment of the present invention includes the steps of: (a) providing a substrate 2; (b) forming a gate electrode 3a on the substrate 2; (c) forming a gate insulating layer 4 on the gate electrode 3a; and (d) forming an oxide semiconductor film on the gate insulating layer 4. The method for fabricating the TFT substrate 100A further includes the step (e) of forming a conductive film on the oxide semiconductor film and patterning the oxide semiconductor film and the conductive film using a single photomask, thereby forming an oxide semiconductor layer 15 and a source line layer including a source electrode 6s, a drain electrode 6d and a source line 6. The method for fabricating the TFT substrate 100A further includes the steps of: (f) performing a resistance lowering process to lower the resistance of a portion of the oxide semiconductor layer 15, thereby forming a conductor region 7 and leaving another portion of the oxide semiconductor layer 15 that has not had its resistance lowered as a semiconductor region 5; and (g) forming an interlayer insulating layer 11 over the conductor region 7. And the method for fabricating the TFT substrate 100A further includes the step (h) of forming a transparent electrode 9 which overlaps at least partially with the conductor region 7 with the interlayer insulating layer 11 interposed between them when viewed along a normal to the substrate 2 so that a hole 9v which overlaps with the source line layer when viewed along a normal to the substrate 2 is cut through the transparent electrode 9.

The method for fabricating the TFT substrate 100A suitably further includes the step (i) of forming a protective layer 8 which contacts with a channel region of the semiconductor region 5 and which covers the source line layer at least partially between the steps (e) and (f). The hole 9v is suitably cut so as to overlap with a portion of the source line layer which is not covered with the protective layer 8 when viewed along a normal to the substrate 2.

The step (f) suitably includes the step (f1) of forming a reducing insulating layer 31 which has the property of reducing an oxide semiconductor included in the semiconductor region 5. The reducing insulating layer 31 is suitably formed so as to cover the source line layer at least partially. The resistance lowering process is suitably performed by the reducing insulating layer 31. And the hole 9v is suitably cut so as to overlap with a portion of the source line layer which is not covered with the reducing insulating layer 31 when viewed along a normal to the substrate 2.

According to this embodiment, the manufacturing process can be simplified, but a TFT substrate 100A which will hardly generate leakage current can still be fabricated.

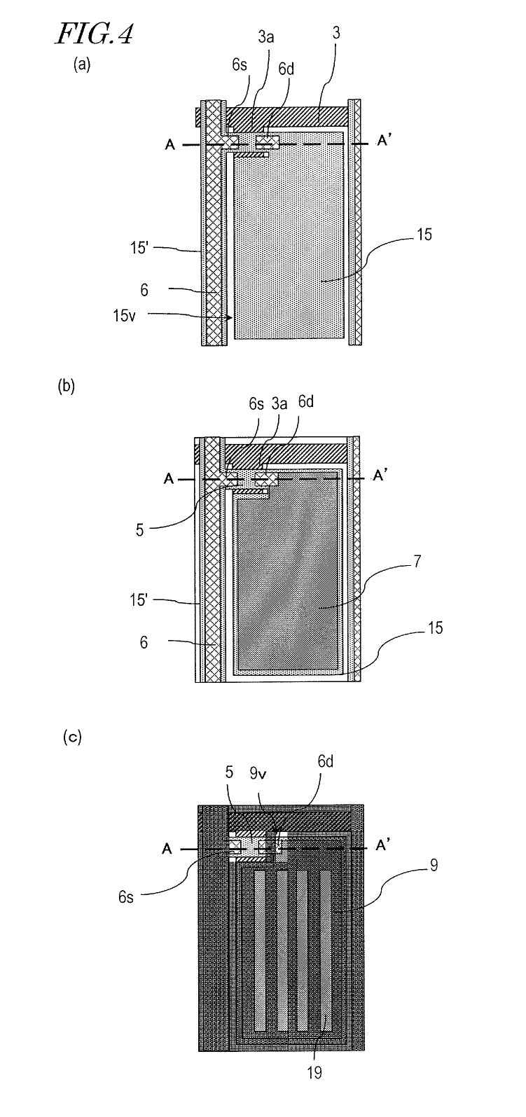

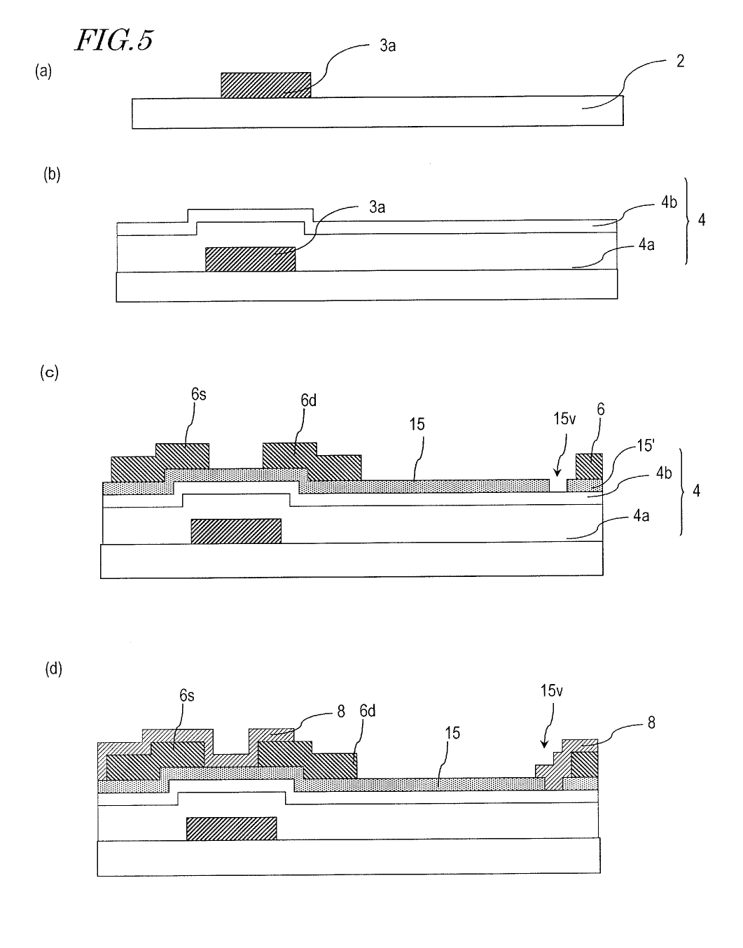

Hereinafter, an exemplary method for fabricating the TFT substrate 100A will be described with reference to FIGS. 4 through 6.

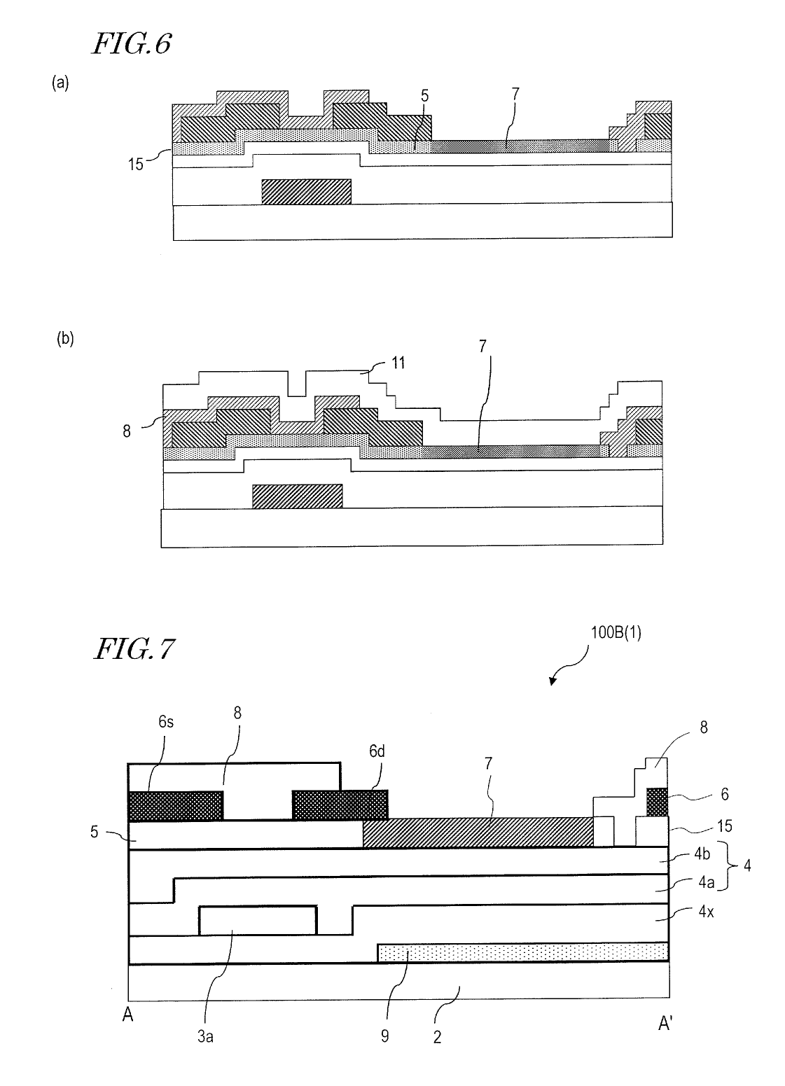

FIGS. 4(a) to 4(c) are schematic plan views illustrating an exemplary method for fabricating the TFT substrate 100A. FIGS. 5(a) to 5(d) and FIGS. 6(a) and 6(b) are schematic cross-sectional views illustrating an exemplary series of manufacturing process steps to fabricate the TFT substrate 100A. FIG. 5(c) is a schematic cross-sectional view as viewed on the plane A-A′ shown in FIG. 4(a) and FIG. 6(a) is a schematic cross-sectional view as viewed on the plane A-A′ shown in FIG. 4(b).

First of all, as shown in FIG. 5(a), a gate electrode 3a and a gate line 3 are formed on a substrate 2. As the substrate 2, a transparent insulating substrate such as a glass substrate, for example, may be used. The gate electrode 3a and gate line 3 may be formed by depositing a conductive film on the substrate 2 by sputtering process and then patterning the conductive film by photolithographic process. In this example, a multilayer film with a double layer structure consisting of a TaN film (with a thickness of about 50 nm) and a W film (with a thickness of about 370 nm) that are stacked one upon the other in this order on the substrate 2 is used as the conductive film. As this conductive film, a single-layer film of Ti, Mo, Ta, W, Cu, Al or Cr, a multilayer film or alloy film including any of these elements in combination, or a metal nitride film thereof may also be used.

Next, as shown in FIG. 5(b), a gate insulating layer 4 is formed so as to cover the gate electrode 3a and the gate line 3 by CVD (chemical vapor deposition) process.

The gate insulating layer 4 may be made of SiO₂, SiNₓ, SiOₓN_{y} (silicon oxynitride, where x>y), SiNₓO_{y} (silicon nitride oxide, where x>y), Al₂O₃, or Ta₂O₅, for example. In this embodiment, the gate insulating layer 4 may be formed to have a multilayer structure comprised of an SiNₓ film (with a thickness of about 325 nm) as the lower layer (lower gate insulating layer 4a) and an SiO₂ film (with a thickness of about 50 nm) as the upper layer (upper gate insulating layer 4b).

Subsequently, an oxide semiconductor film (not shown) is deposited on the gate insulating layer 4 by sputtering process, for example. In this embodiment, an In—Ga—Zn—O based film is used as the oxide semiconductor film, which may have a thickness of about 50 nm, for example.

Subsequently, a conductive film (not shown) is deposited on the oxide semiconductor film by sputtering process, for example. In this example, a conductive film with a multilayer structure consisting of Ti, Al and Ti layers was used as the conductive film. The lower Ti layer may have a thickness of about 50 nm, the Al layer may have as thickness of about 200 nm, and the upper Ti layer may have a thickness of about 100 nm.

Thereafter, as shown in FIGS. 4(a) and 5(c), by performing a half-tone exposure process using a single photomask (half-tone mask), a resist film with varying thicknesses is formed on the conductive film. After that, an oxide semiconductor layer 15 is formed out of the oxide semiconductor film and a source electrode 6s, a drain electrode 6d and a source line 6 are formed out of the conductive film by dry etching and ashing processes, for example. Since the oxide semiconductor layer 15, source and drain electrodes 6s, 6d and source line 6a can be formed using a single photomask in this manner, the manufacturing cost can be cut down.

Also, inside the pixel, a hole 15v is created around the oxide semiconductor layer 15 and a part of the hole 15v is located in the vicinity of the source line 6. By cutting this hole 15v, the oxide semiconductor layer 15 can be split into a portion which accounts for almost the entire pixel and a portion which is located under the source line 6 (which will be referred to herein as an “oxide semiconductor layer 15′”).

Subsequently, as shown in FIG. 5(d), a protective layer 8 is formed by CVD and photolithographic processes, for example, so as to cover the channel region of the oxide semiconductor film 15. In this process step, the hole 15v is filled with the protective layer 8, and an end portion of the oxide semiconductor layer 15 closer to the source line 6 gets covered with the protective layer 8. In some cases, almost the entire outer periphery of the oxide semiconductor layer 15 may get covered with the protective layer 8. In addition, at least a portion of the source line layer and an end portion of the oxide semiconductor layer 15′ may also get covered with the protective layer 8. The protective layer 8 may be made of an insulating oxide (such as SiO₂), for example, and may have a thickness of about 100 nm. Also, when viewed along a normal to the substrate 2, an end portion of the protective layer 8 suitably overlaps with the drain electrode 6d. Then, the oxide semiconductor layer 15 will be able to have its resistance lowered to its portion which is located near the end portion of the drain electrode 6d and a conductor region (transparent electrode) 7 will be formed in a subsequent process step.

Thereafter, as shown in FIGS. 6(a) and 4(b), a conductor region 7 is defined by subjecting a portion of the oxide semiconductor layer 15 to a resistance lowering process. Specifically, a portion of the oxide semiconductor layer 15 which is not covered with any of the source and drain electrodes 6s, 6d, the source line 6a and the protective layer 8 has had its resistance lowered to be a conductor region 7. Meanwhile, the rest of the oxide semiconductor layer 15 that has not had its resistance lowered is left as a semiconductor region 5. The electrical resistance of that portion that has been subjected to the resistance lowering process (which will be referred to herein as a “low-resistance portion”) is lower than that of the portion that has not been subjected to the resistance lowering process (which will be referred to herein as a “high-resistance portion”).

The resistance lowering process may be plasma processing or doping a p-type dopant or an n-type dopant, for example. If a region that needs to have its resistance lowered is doped with a p-type dopant or an n-type dopant, then the dopant concentration of the conductor region 7 becomes higher than that of the semiconductor region 5.

Due to diffusion of the dopant, sometimes a portion of the oxide semiconductor layer 15 which is located under an end portion of the drain electrode 6d may also have its resistance lowered and eventually form part of the conductor region 7. In that case, the conductor region 7 will contact directly with the drain electrode 6d.

Examples of alternative resistance lowering processes include hydrogen plasma processing using a CVD system, argon plasma processing using an etching system, and an annealing process under a reducing ambient.

Thereafter, as shown in FIG. 6(b), an interlayer insulating layer (passivation layer, dielectric layer) 11 is formed on the protective layer 8. In this embodiment, an SiO₂ film (with a thickness of 200 nm, for example) is deposited as the interlayer insulating layer 11. In this example, the interlayer insulating layer 11 is formed to contact with the conductor region 7.

Thereafter, if it is necessary according to the display mode adopted, a transparent conductive film may be deposited as shown in FIGS. 1(b) and 4(c) to a thickness of 100 nm, for example, on the interlayer insulating layer 11 and then patterned to form a transparent electrode 9. As the transparent conductive film, an ITO (indium tin oxide) film, an IZO film or any other suitable film may be used. A hole 9v is cut through the transparent electrode 9 so as to overlap with the source line layer (such as the drain electrode 6d). Also, the hole 9v is created so as to overlap with a portion of the drain electrode 6d which is not covered with the protective layer 8. In the example illustrated in FIG. 4(c), to use this TFT substrate 100A in an FFS mode liquid crystal display device 500, at least one slit is cut through the transparent electrode 9.

According to such a method, a TFT substrate 100A which will hardly generate leakage current can be fabricated with an increase in the number of manufacturing process steps or the number of masks to use minimized.

Hereinafter, a TFT substrate 100B(1) according to another embodiment of the present invention will be described with reference to FIG. 7, in which any component also included in the TFT substrate 100A and having substantially the same function as its counterpart is identified by the same reference numeral as its counterpart's and description thereof will be omitted herein to avoid redundancies.

FIG. 7 is a schematic cross-sectional view of the TFT substrate 100B(1) and corresponds to FIG. 1(b).

In this TFT substrate 100B(1), a transparent electrode 9 is formed on the substrate 2, an insulating layer 4x is formed on the transparent electrode 9, a gate electrode 3a is formed on the insulating layer 4x, and the transparent electrode 9 has no hole 9v, which are differences from the TFT substrate 100A.

The insulating layer 4x may be formed out of an insulating film to be the gate insulating layer 4 described above, and may have a thickness of about 100 nm, for example.

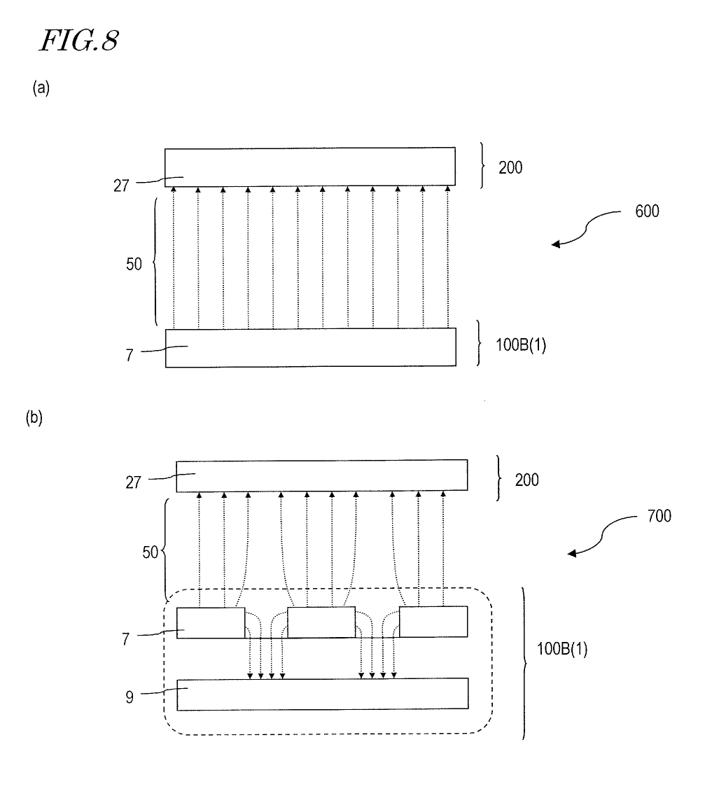

Next, liquid crystal display devices 600 and 700, each including the TFT substrate 100B(1), will be described with reference to FIG. 8.

FIGS. 8(a) and 8(b) are schematic cross-sectional views of the liquid crystal display devices 600 and 700, respectively.

In this TFT substrate 100B(1), the transparent electrode (common electrode) 9 is located closer to the substrate 2 than the conductor region 7 (pixel electrode) is. That is why this TFT substrate 100B(1) can be used in not only the FFS mode liquid crystal display device 500 but also liquid crystal display devices in any of various other liquid crystal modes as well.

For example, this TFT substrate 100B(1) may be used in a vertical electric field mode liquid crystal display device 600 as shown in FIG. 8(a) in which a counter electrode 27 is arranged on one surface of the counter substrate 200 to face the liquid crystal layer and which conducts a display operation by controlling the alignments of liquid crystal molecules in the liquid crystal layer 50 with a vertical electric field generated by the counter electrode 27 and the conductor region 7. In that case, slits do not have to be cut through the conductor region 7.

Furthermore, the TFT substrate 100B(1) may also be used in a vertical/lateral electric field mode liquid crystal display device 700 as shown in FIG. 8(b) in which a counter electrode 27 is arranged on one surface of the counter substrate 200 to face the liquid crystal layer 50 and slits are cut through the conductor region 7 and which conducts a display operation by controlling the alignments of liquid crystal molecules in the liquid crystal layer 50 with a lateral electric field generated by the conductor region 7 and the transparent electrode 9 and with a vertical electric field generated by the conductor region 7 and the counter electrode 27. Such a liquid crystal display device 700 is disclosed in PCT International Application Publication No. 2012/053415, for example.

Consequently, this TFT substrate 100B(1) is applicable more effectively to various liquid crystal display modes than a TFT substrate in which the pixel electrodes are arranged closer to the substrate than the common electrode is.

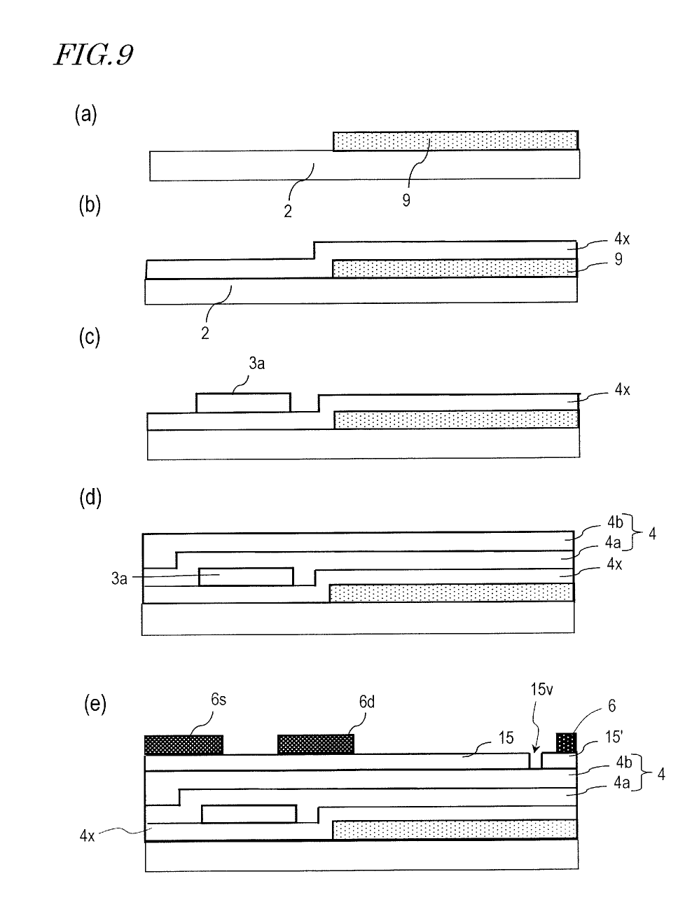

Hereinafter, an exemplary method for fabricating the TFT substrate 100B(1) will be described with reference to FIG. 9. FIGS. 9(a) to 9(e) are schematic cross-sectional views illustrating respective manufacturing process steps to fabricate the TFT substrate 100B(1).

First of all, as shown in FIG. 9(a), a transparent electrode 9 is formed on the substrate 2 by the method described above.

Next, as shown in FIG. 9(b), an insulating layer 4x is deposited on the transparent electrode 9 by CVD process, for example. The insulating layer 4x may be made of SiNₓ, for example, and may have a thickness of approximately 100 nm.

Subsequently, as shown in FIG. 9(c), a gate electrode 3a and other conductive members are formed on the insulating layer 4x by the method described above. It should be noted that when viewed along a normal to the substrate 2, the gate electrode 3a does not overlap with the transparent electrode 9.

Next, as shown in FIG. 9(d), a gate insulating layer 4 (consisting of a lower gate insulating layer 4a and an upper gate insulating layer 4b) is formed by the method described above so as to cover the gate electrode 3a.

Subsequently, an oxide semiconductor film and a conductive film are formed as described above. Thereafter, as described above, by performing a half-tone exposure process using a single photomask (half-tone mask) and dry etching and aching processes, the oxide semiconductor film and the conductive film are patterned simultaneously, thereby forming an oxide semiconductor layer 15, a source electrode 6s, a drain electrode 6d, and a source line 6 and cutting the hole 15v described above as shown in FIG. 9(e). Since not only the source and drain electrodes 6s, 6d and source line 6a but also the oxide semiconductor layer 15 can be formed using a single photomask in this manner, the manufacturing process can be simplified and the manufacturing cost can be cut down.

Then, as shown in FIG. 7, a protective layer 8 is formed so as to cover the channel region of the oxide semiconductor layer 15. In this process step, the protective layer 8 is formed so as to cover the hole 15v as described above.

Thereafter, the resistance lowering process is performed by the method described above, thereby defining a conductor region 7 in the oxide semiconductor layer 15 and completing the TFT substrate 100B(1).

This TFT substrate 100B(1) may be modified into a TFT substrate 100B(2) to be described below.

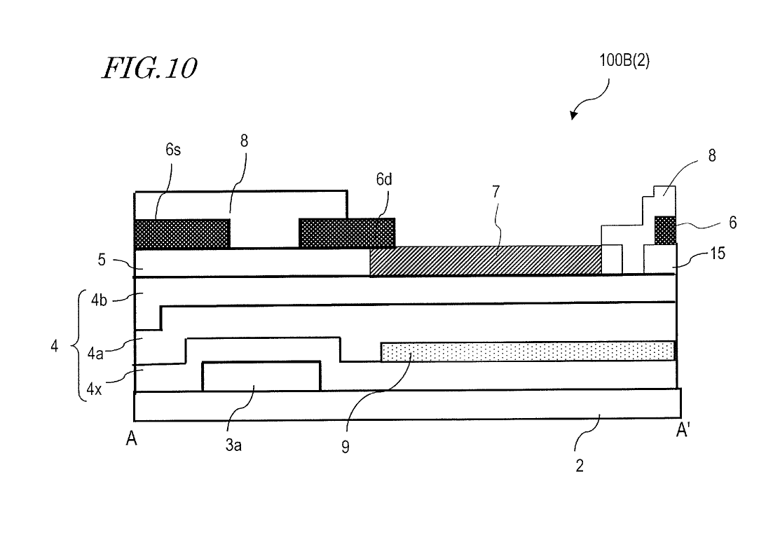

FIG. 10 is a schematic cross-sectional view of the TFT substrate 100B(2) and corresponds to FIG. 7. In FIG. 10, any component also included in the TFT substrate 100B(1) and having substantially the same function as its counterpart is identified by the same reference numeral as its counterpart's and description thereof will be omitted herein to avoid redundancies.

In this TFT substrate 100B(2), the gate electrode 3a is arranged closer to the substrate 2 than the transparent electrode 9 is, which is a difference from the TFT substrate 100B(1).

This TFT substrate 100B(2) includes a gate electrode 3a which is formed on the substrate 2, an insulating layer 4x which is formed on the gate electrode 3a, and a transparent electrode 9 which is formed on the insulating layer 4x.

Hereinafter, an exemplary method for fabricating the TFT substrate 100B(2) will be described briefly with reference to FIG. 11. FIGS. 11(a) to 11(c) are schematic cross-sectional views illustrating respective manufacturing process steps to fabricate the TFT substrate 100B(2).

First, as shown in FIG. 11(a), a gate electrode 3a is formed on the substrate 2 by the method described above.

Next, as shown in FIG. 11(b), an insulating layer 4x is formed on the gate electrode 3a by the method described above.

Subsequently, as shown in FIG. 11(c), a transparent electrode 9 is formed on the insulating layer 4x by the method described above.

Thereafter, a gate insulating layer 4 is formed on the transparent electrode 9, an oxide semiconductor layer 15 and 15′ is formed on the gate insulating layer 4 and a hole 15v is cut through the oxide semiconductor layer 15 and 15′, source and drain electrodes 6s, 6d are formed on the oxide semiconductor layer 15, and a source line 6 is formed on the oxide semiconductor layer 15′ by the methods described above.

Finally, a protective layer 8 is formed by the method described above to cover the channel region of the oxide semiconductor layer 15 and to fill the hole 15v and the resistance lowering process is performed, thereby defining a semiconductor region 5 and a conductor region 7 in the oxide semiconductor layer 15 and completing the TFT substrate 100B(2).

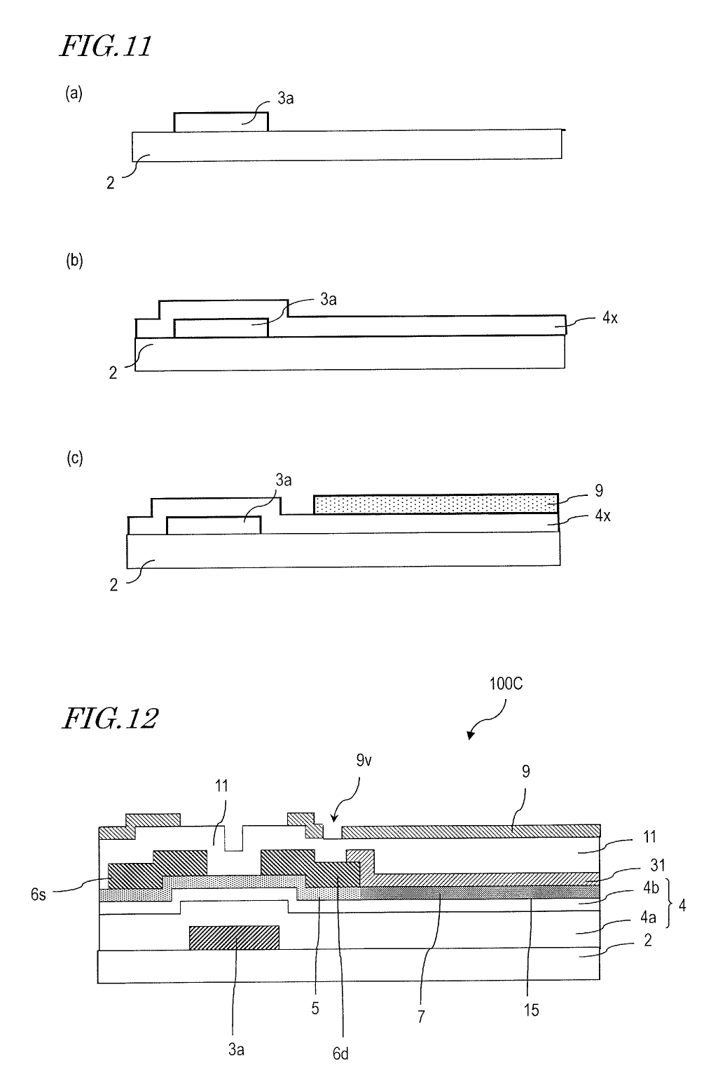

Hereinafter, a TFT substrate 100C according to still another embodiment of the present invention will be described with reference to FIG. 12, in which any component also included in the TFT substrate 100A and having substantially the same function as its counterpart is identified by the same reference numeral as its counterpart's and description thereof will be omitted herein to avoid redundancies.

FIG. 12 is a schematic cross-sectional view of the TFT substrate 100C and corresponds to FIG. 1(b).

In this TFT substrate 100C, the protective layer 8 is replaced with a reducing insulating layer 31 which contacts with the conductor region 7, which is a difference from the TFT substrate 100A. The reducing insulating layer 31 does not contact with the semiconductor region 5.

Also, in this TFT substrate 100C, the transparent electrode 9 has a hole 9v which overlaps with the drain electrode 6d when viewed along a normal to the substrate 2. The hole 9v is suitably arranged so as to overlap with a portion of the drain electrode 6d which is not covered with the reducing insulating layer 31.

The reducing insulating layer 31 has the property of reducing an oxide semiconductor included in the semiconductor region 5. That is why even without performing any special resistance lowering process such as the plasma processing described above, if the reducing insulating layer 31 is arranged to contact with a region of the oxide semiconductor layer 15 that needs to turn into a conductor, then hydrogen, for example, included in the reducing insulating layer 31 will diffuse to enter and reduce a portion of the oxide semiconductor layer 15, thereby defining a conductor region 7. As a result, there is no need to perform any special resistance lowering process, and therefore, the manufacturing cost can be cut down.

The reducing insulating layer 31 may be made of SiNₓ, for example. The thickness of the reducing insulating layer 31 suitably falls within the range of about 50 nm to about 300 nm. In this embodiment, the reducing insulating layer 31 may have a thickness of about 100 nm, for example.

The reducing insulating layer 31 may be formed at a substrate temperature of about 100° C. to about 250° C. (e.g., at 220° C.) and with the flow rates of SiH₄ and NH₃ gases adjusted so that the flow rate ratio (in sscm) of an SiH₄ and NH₃ mixed gas (i.e., the ratio of the flow rate of SiH₄ to the flow rate of NH₃) falls within the range of 4 to 20.

Although the reducing insulating layer 31 shown in FIG. 12 contacts with a portion of the upper surface of the oxide semiconductor layer 15, the reducing insulating layer 31 may also be arranged so as to contact a portion of the lower surface of the oxide semiconductor layer 15.

A portion of the reducing insulating layer 31 is suitably arranged on the source line layer (e.g., on the drain electrode 6d) and suitably covers the source line layer at least partially. As a result, the distance between the transparent electrode 9 and the drain electrode 6d increases too much to generate leakage current easily.

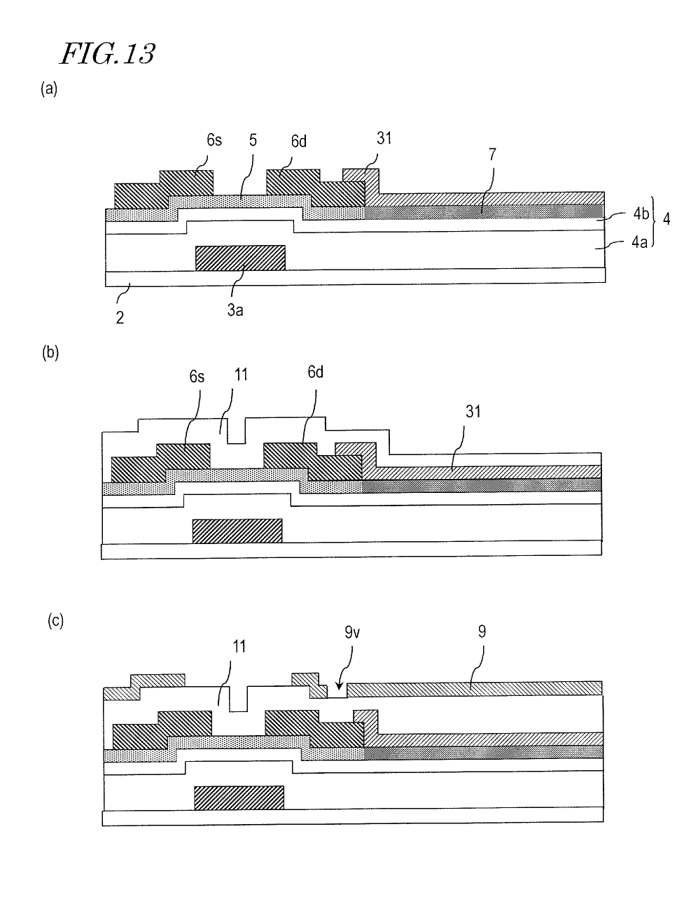

Hereinafter, an exemplary method for fabricating the TFT substrate 100C will be described with reference to FIG. 13. FIGS. 13(a) to 13(c) are schematic cross-sectional views illustrating respective manufacturing process steps to fabricate the TFT substrate 100C.

A gate electrode 3a, a gate insulating layer 4, an oxide semiconductor layer 15, a source electrode 6s and a drain electrode 6d are formed on the substrate 2 by the methods described above.

Next, as shown in FIG. 13(a), a reducing insulating layer 31 is formed by CVD process, for example, so as to contact with a portion of the oxide semiconductor layer 15 that needs to turn into a conductor region 7. The reducing insulating layer 31 may be made of SiNₓ and may have a thickness of about 100 nm, for example. A portion of the reducing insulating layer 31 is suitably arranged on the source line layer (e.g., on the drain electrode 6d and source line 6). Although the reducing insulating layer 31 shown in FIG. 13(a) is arranged to contact with the upper surface of the oxide semiconductor layer 15, the reducing insulating layer 31 may also be formed before the oxide semiconductor layer 15 is formed and may contact with the lower surface of the oxide semiconductor layer 15. The reducing insulating layer 31 is arranged so as to be out of contact with a portion of the oxide semiconductor layer 15 to be a semiconductor region 5. And the reducing insulating layer 31 is arranged so as not to contact with a portion of the oxide semiconductor layer 15 to be a channel region.

The reducing insulating layer 31 may be formed at a substrate temperature of about 100° C. to about 250° C. (e.g., at 220° C.) and with the flow rates of SiH₄ and NH₃ gases adjusted so that the flow rate ratio (in sscm) of an SiH₄ and NH₃ mixed gas (i.e., the ratio of the flow rate of SiH₄ to the flow rate of NH₃) falls within the range of 4 to 20.

A portion of the oxide semiconductor layer 15 which has been reduced by the reducing insulating layer 31 becomes a conductor region 7, while the rest of the oxide semiconductor layer 15 which has not been reduced becomes a semiconductor region 5. That is to say, even without performing any special resistance-lowering process, a portion of the oxide semiconductor layer 15 is reduced, and has its resistance lowered, by hydrogen, for example, included in the reducing insulating layer 31, thus defining a conductor region 7. Since there is no need to perform any special resistance lowering process, the manufacturing cost can be cut down.

Next, as shown in FIG. 13(b), an interlayer insulating layer 11 is formed by the method described above on the source and drain electrodes 6s, 6d and the reducing insulating layer 31.

Subsequently, as shown in FIG. 13(c), a transparent electrode 9 is formed on the interlayer insulating layer 11 by the method described above. A hole 9v is cut through the transparent electrode 9 and is arranged so as to overlap with the drain electrode 6d when viewed along a normal to the substrate 2. More suitably, the hole 9v is arranged so as to overlap with a portion of the drain electrode 6d which is not covered with the reducing insulating layer 31.

As can be seen from the foregoing description, embodiments of the present invention provide a semiconductor device which can be fabricated by a simple process with the decrease in yield checked and also provide a method for fabricating such a semiconductor device.

### INDUSTRIAL APPLICABILITY

The present invention is applicable broadly to various types of devices that use a thin-film transistor. Examples of such devices include circuit boards such as an active-matrix substrate, display devices such as a liquid crystal display, an organic electroluminescence (EL) display, and an inorganic electroluminescence display, image capture devices such as an image sensor, and electronic devices such as an image input device and a fingerprint scanner.

### REFERENCE SIGNS LIST

2 substrate
3a gate electrode
3 gate line
4 gate insulating layer
5 semiconductor region
6s source electrode
6d drain electrode
6 source line
7 conductor region
8 protective layer
9 transparent electrode
9v, 15v hole
11 interlayer insulating layer
15, 15′ oxide layer
100A semiconductor device (TFT substrate)

1. A semiconductor device comprising:
a substrate;
a gate electrode formed on the substrate;
a first insulating layer formed on the gate electrode;
an oxide layer which is formed on the first insulating layer and which includes a semiconductor region and a conductor region, wherein the semiconductor region overlaps at least partially with the gate electrode with the first insulating layer interposed between them;
a source electrode and a drain electrode which are electrically connected to the semiconductor region;
a source line electrically connected to the source electrode;
a protective layer which covers a channel region of the semiconductor region, does not cover at least a portion of the conductor region, and covers at least partially an end portion of the oxide layer; and
a transparent electrode arranged so as to overlap at least partially with the conductor region when viewed along a normal to the substrate.

2. The semiconductor device of claim 1, wherein the drain electrode contacts with a portion of the upper surface of the conductor region.

3. The semiconductor device of claim 1, further comprising an interlayer insulating layer formed on the protective layer,
wherein the transparent electrode is formed on the interlayer insulating layer, and
the conductor region overlaps at least partially with the transparent electrode with the interlayer insulating layer interposed between them.

4. The semiconductor device of claim 1, wherein the first insulating layer is formed on the transparent electrode, and
the conductor region overlaps at least partially with the transparent electrode with the first insulating layer interposed between them.

5. The semiconductor device of claim 4, further comprising a second insulating layer,
wherein the second insulating layer is formed on the gate electrode, and
the transparent electrode is formed on the second insulating layer.

6. The semiconductor device of claim 4, further comprising a second insulating layer,
wherein the second insulating layer is formed on the transparent electrode, and
the gate electrode is formed on the second insulating layer.

7. A semiconductor device comprising:
a substrate;
a gate electrode formed on the substrate;
a gate insulating layer formed on the gate electrode;
an oxide layer which is formed on the gate insulating layer and which includes a semiconductor region and a conductor region, wherein the semiconductor region overlaps at least partially with the gate electrode with the gate insulating layer interposed between them;
a source electrode and a drain electrode which are electrically connected to the semiconductor region;
a source line electrically connected to the source electrode;
an interlayer insulating layer formed on a source line layer including the source and drain electrodes and the source line; and
a transparent electrode arranged so as to overlap at least partially with the conductor region with the interlayer insulating layer interposed between them when viewed along a normal to the substrate,
wherein the transparent electrode has a hole which overlaps with the source line layer when viewed along a normal to the substrate.

8. The semiconductor device of claim 7, further comprising a protective layer which contacts with a channel region of the semiconductor region and which covers at least a portion of the source line layer,
wherein the hole overlaps with a portion of the source line layer which is not covered with the protective layer when viewed along a normal to the substrate.

9. The semiconductor device of claim 7, further comprising a reducing insulating layer which has the property of reducing an oxide semiconductor included in the semiconductor region,
wherein the reducing insulating layer contacts with the conductor region but does not contact with the semiconductor region, and covers the source line layer at least partially, and
the hole overlaps with a portion of the source line layer which is not covered with the reducing insulating layer when viewed along a normal to the substrate.

10. The semiconductor device of claim 1, wherein the oxide layer includes In, Ga and Zn.

11. A method for fabricating a semiconductor device, the method comprising the steps of:
(a) providing a substrate;
(b) forming a gate electrode on the substrate;
(c) forming a first insulating layer on the gate electrode;
(d) forming an oxide semiconductor film on the first insulating layer;
(e) performing the step (e1) of forming a conductive film on the oxide semiconductor film and patterning the oxide semiconductor film and the conductive film using a single photomask, thereby forming an oxide semiconductor layer and a source line layer including a source electrode, a drain electrode and a source line, and the step (e2) of forming a protective layer which protects a channel region of the oxide semiconductor layer and at least a part of an end portion of the oxide semiconductor layer and performing a resistance lowering process to lower the resistance of a portion of the oxide semiconductor layer, thereby forming a conductor region and leaving another portion of the oxide semiconductor layer that has not had its resistance lowered as a semiconductor region; and
(f) forming a transparent electrode which overlaps at least partially with the conductor region when viewed along a normal to the substrate.

12. The method of claim 11, wherein the step (f) is performed after the step (e) has been performed.

13. The method of claim 11, wherein the step (f) is performed between the steps (a) and (b).

14. The method of claim 11, wherein the step (f) is performed between the steps (c) and (d).

15. A method for fabricating a semiconductor device, the method comprising the steps of:
(a) providing a substrate;
(b) forming a gate electrode on the substrate;
(c) forming a gate insulating layer on the gate electrode;
(d) forming an oxide semiconductor film on the gate insulating layer;
(e) forming a conductive film on the oxide semiconductor film and patterning the oxide semiconductor film and the conductive film using a single photomask, thereby forming an oxide semiconductor layer and a source line layer including a source electrode, a drain electrode and a source line;
(f) performing a resistance lowering process to lower the resistance of a portion of the oxide semiconductor layer, thereby forming a conductor region and leaving another portion of the oxide semiconductor layer that has not had its resistance lowered as a semiconductor region;
(g) forming an interlayer insulating layer on the conductor region; and
(h) forming a transparent electrode which overlaps at least partially with the conductor region with the interlayer insulating layer interposed between them when viewed along a normal to the substrate so that a hole which overlaps with the source line layer when viewed along a normal to the substrate is cut through the transparent electrode.

16. The method of claim 15, further comprising the step (i) of forming a protective layer which contacts with a channel region of the semiconductor region and which covers the source line layer at least partially between the steps (e) and (f),
wherein the hole is cut so as to overlap with a portion of the source line layer which is not covered with the protective layer when viewed along a normal to the substrate.

17. The method of claim 15, wherein the step (f) includes the step (f1) of forming a reducing insulating layer which has the property of reducing an oxide semiconductor included in the semiconductor region,
the reducing insulating layer is formed so as to cover the source line layer at least partially,
the resistance lowering process is performed by the reducing insulating layer, and
the hole is cut so as to overlap with a portion of the source line layer which is not covered with the reducing insulating layer when viewed along a normal to the substrate.

18. The semiconductor device of claim 7, wherein the oxide layer includes In, Ga and Zn.

19. The method of claim 11, wherein the oxide layer includes In, Ga and Zn.

20. The method of claim 15, wherein the oxide layer includes In, Ga and Zn.
